(19) United States
(12) Patent Application Publication
(10) Pub. No.: US 2024/0212072 A1
(43) Pub. Date: Jun. 27, 2024

(54) SCHEDULING METHOD, SYSTEM AND DEVICE FOR UNIFORMLY REDUCING ENERGY AND MAINTENANCE COSTS OF WATER SUPPLY PIPE NETWORK SYSTEM

(71) Applicant: GUANGDONG UNIVERSITY OF TECHNOLOGY, Guangzhou (CN)

(72) Inventors: Qi WANG, Guangzhou (CN); Zhiwei ZHAO, Guangzhou (CN); Bailin LUO, Guangzhou (CN); Yixin WU, Guangzhou (CN); Yiyu KOU, Guangzhou (CN); Tianqi LI, Guangzhou (CN); Ruichen HUANG, Guangzhou (CN); Zhongyi MEI, Guangzhou (CN)

(21) Appl. No.: 18/395,670

(22) Filed: Dec. 25, 2023

(30) Foreign Application Priority Data
Dec. 26, 2022 (CN) 202211676663.6

(51) Int. Cl. G06Q 50/06; G06F 30/18; G06F 30/27

(52) U.S. Cl. CPC G06Q 50/06; G06F 30/18; G06F 30/27

(57) ABSTRACT

A scheduling method, system and device for uniformly reducing energy and maintenance costs of a water supply pipe network system. The method comprises: acquiring a topological structure and operation data of the system, constructing a high-dimensional multi-objective optimization model for water pump scheduling of the system, and setting a decision variable, an objective function and a constraint condition of the model, the high-dimensional multi-objective optimization model taking an energy cost and a maintenance cost of each water pump in the system as independent optimization objectives; solving the high-dimensional multi-objective optimization model by applying an optimization algorithm to obtain a Pareto optimal solution set; and based on the Pareto optimal solution set, screening and outputting a scheduling scheme for cooperatively reducing the energy cost and the maintenance cost of the water pump by drawing a parallel coordinate graph for visual comparison and using a two-factor sorting method.

### CROSS REFERENCE TO RELATED APPLICATIONS

This application claims foreign priority of Chinese Patent Application No. 202211676663.6, filed on Dec. 26, 2022 in the China National Intellectual Property Administration, the disclosures of all of which are hereby incorporated by reference.

### TECHNICAL FIELD

The present invention relates to the technical field of water supply pipe network systems, and more particularly to a scheduling method, system and device for uniformly reducing energy and maintenance costs of a water supply pipe network system.

### BACKGROUND OF THE PRESENT INVENTION

With the rapid development of cities, a scope of a water supply pipe network has been gradually expanded, and a total amount of water supply has also been increased. The accompanying energy consumption of water supply industry has also been significantly increased. There will be a lot of energy consumption, related greenhouse gas emissions and water loss during the operation of a water supply system. In the water supply industry in China, power consumption accounts for the largest proportion of the total energy consumption in the water supply industry, wherein the power consumption of water pumps accounts for 30% to 50% of water production costs of water plants. Therefore, the reduction of the power consumption of water pumps and the optimization of pumping station scheduling are the keys to energy saving and consumption reduction in the water supply industry.

At present, the scheduling of the water supply pipe network system mainly focuses on an energy-saving scheduling control system of a secondary water supply facility, such as reducing the energy consumption of a water supply pump house by optimizing a control mode, and realizing constant-pressure water supply at a terminal in combination with a stepless frequency conversion technology. However, a logical control rule and a constraint between nodes in the water supply pipe network system are not considered in this method, and a resulting scheduling scheme has certain limitations.

### SUMMARY OF THE PRESENT INVENTION

In order to overcome the defects of high energy and maintenance costs and certain limitations on a scheduling scheme of a water supply pipe network system in the prior art above, the present invention provides a scheduling method, system and device for uniformly reducing energy and maintenance costs of a water supply pipe network system.

In order to solve the above technical problems, technical solutions of the present invention are as follows.

A scheduling method for uniformly reducing energy and maintenance costs of a water supply pipe network system comprises the following steps of:
S1: acquiring a topological structure and operation data of the water supply pipe network system, constructing a high-dimensional multi-objective optimization model for water pump scheduling of the water supply pipe network system, and setting a decision variable, an objective function and a constraint condition of the model, wherein the high-dimensional multi-objective optimization model takes an energy cost and a maintenance cost of each water pump in the water supply pipe network system as independent optimization objectives;
S2: solving the high-dimensional multi-objective optimization model by applying an optimization algorithm to obtain a Pareto optimal solution set; and
S3: based on the Pareto optimal solution set, screening and outputting a scheduling scheme for cooperatively reducing the energy cost and the maintenance cost of the water pump by drawing a parallel coordinate graph for visual comparison and using a two-factor sorting method.

As a preferred solution, the operation data of the water supply pipe network system comprises operation conditions and actual peak-valley price periods of each water pump and each water tank, and an operation requirement of the water supply pipe network system.

As a preferred solution, the step S1 specifically comprises the following steps of:
S11: acquiring the topological structure of the water supply pipe network system, determining a control correlation between each water pump and each water tank, and setting the decision variable of the scheduling model according to a logical control rule of each water pump;
S12: determining calculation methods of the energy cost and the maintenance cost of the water pump according to the actual peak-valley price period for setting the objective function of the scheduling model; and
S13: setting the constraint condition of the scheduling model according to the operation requirement of the water supply pipe network system.

As a preferred solution, in the step S11, the control correlation between each water pump and each water tank is determined according to the topological structure and an operation mode of the water supply pipe network; and the decision variable comprises a switch control water level of each water pump associated with each water tank at a peak-valley price, and the control rule of each water pump is set by using rule-based control functions in EPANET 2.2.

As a preferred solution, the objective function of the comprises high-dimensional multi-objective optimization model minimizing the energy cost and the maintenance cost of each water pump; and an expression of the objective function is as follows:

$$\{ \begin{matrix}min {C}_{E}^{1} \\ min {C}_{E}^{2} \\ … \\ min {C}_{E}^{NP} \\ \\ min {C}_{M}^{1} \\ min {C}_{M}^{2} \\ … \\ min {C}_{M}^{NP}\end{matrix}$$

wherein, NP represents a number of pumps, C_{E}ⁱ represents an energy cost of a water pump i, and C_{M}ⁱ represents a maintenance cost of the water pump i; wherein, the energy cost of the water pump comprises an electricity charge of one simulation cycle, and the maintenance cost of the water pump comprises a total number of switches of one simulation cycle.

As a preferred solution, the constraint condition comprises mass conservation of nodes and energy conservation of pipe sections in the water supply pipe network system, limited water levels in different time periods of each water tank, a switch time interval of the water pump, and a minimum service pressure constraint of a water demand node.

As a preferred solution, the step S3 specifically comprises the following step of: drawing the Pareto optimal solution in the parallel coordinate graph, screening an energy-saving scheduling scheme with a comprehensive benefit advantage as the scheduling scheme for cooperatively reducing the energy cost and the maintenance cost of the water pump through the two-factor sorting method and the visual comparison analysis, and outputting the scheduling scheme.

Further, the present invention further provides a scheduling system for uniformly reducing energy and maintenance costs of a water supply pipe network system, which applies the scheduling method provided by any one of the technical solutions above. The system comprises a water supply pipe network data acquisition module, a water pump scheduling optimization module and a scheduling scheme screening module, wherein:
the water pump scheduling optimization module is configured with the high-dimensional multi-objective optimization model, the decision variable, the objective function and the constraint condition are preset for the high-dimensional multi-objective optimization model, and the high-dimensional multi-objective optimization model takes the energy cost and the maintenance cost of each water pump as the independent optimization objectives;
the water pump scheduling optimization module solves the high-dimensional multi-objective optimization model for water pump scheduling by applying the optimization algorithm to obtain the Pareto optimal solution set;
the water supply pipe network data acquisition module is configured for acquiring a topological structure and operation data of a current water supply pipe network system, and updating parameters of the high-dimensional multi-objective optimization model in the water pump scheduling optimization module; and
the scheduling scheme screening module is configured for screening and outputting the scheduling scheme for cooperatively reducing the energy cost and the maintenance cost of the water pump by drawing the parallel coordinate graph for visual comparison and using the two-factor sorting method according to the Pareto optimal solution set generated by the water pump scheduling optimization module.

As a preferred solution, the water supply pipe network data acquisition module acquires the topological structure and the operation data of the current water supply pipe network system, determines the control correlation between each water pump and each water tank, and obtains the logical control rule of each water pump for updating the decision variable of the high-dimensional multi-objective optimization model;
the water supply pipe network data acquisition module further determines the calculation methods of the energy cost and the maintenance cost of the water pump for updating the objective function of the high-dimensional multi-objective optimization model according to the acquired actual peak-valley price period; and
the water supply pipe network data acquisition module further updates the constraint condition of the high-dimensional multi-objective optimization model according to the acquired operation requirement of the water supply pipe network system.

Further, the present invention further provides a scheduling device, which comprises a memory and a processor, wherein the memory stores a computer program, and when executing the computer program, the processor implements the steps in the scheduling method for uniformly reducing the energy and maintenance costs of the water supply pipe network system provided by the present invention.

Compared with the prior art, the technical solutions of the present invention have the beneficial effects that: according to the present invention, by constructing the high-dimensional multi-objective optimization model for water pump scheduling of the water supply pipe network system, and taking the energy cost and the maintenance cost of each water pump as the independent optimization objectives, a uniform scheduling strategy is sought from a microscopic perspective of a scheduling object, and an energy-saving scheduling scheme for a pumping station with a more comprehensive efficiency advantage can be found, so that the energy cost and the maintenance cost of the water supply pipe network system are significantly reduced, and a load imbalance problem existing in a traditional optimal scheduling model for the pumping station is effectively solved.

### DESCRIPTION OF THE DRAWINGS

FIG. 1 is a flow chart of a scheduling method for uniformly reducing energy and maintenance costs of a water supply pipe network system in Embodiment 1.

FIG. 2 is a schematic diagram of a topological structure of a vanZyl pipe network in Embodiment 2.

FIG. 3 is a schematic diagram of a Pareto optimal solution set obtained by the present invention.

FIG. 4 is a schematic diagram of a Pareto optimal solution set obtained by minimizing a total energy cost and a total maintenance cost as an objective function.

FIG. 5 is an architecture diagram of a scheduling system for uniformly reducing energy and maintenance costs of a water supply pipe network system in Embodiment 3.

### DETAILED DESCRIPTION OF PREFERRED EMBODIMENTS

The drawings are only used for illustration, and cannot be understood as limiting the patent.

It is understandable to those skilled in the art that some well-known structures in the drawings and the descriptions thereof may be omitted.

Technical solutions of the present invention are further described hereinafter with reference to the drawings and embodiments.

### Embodiment 1

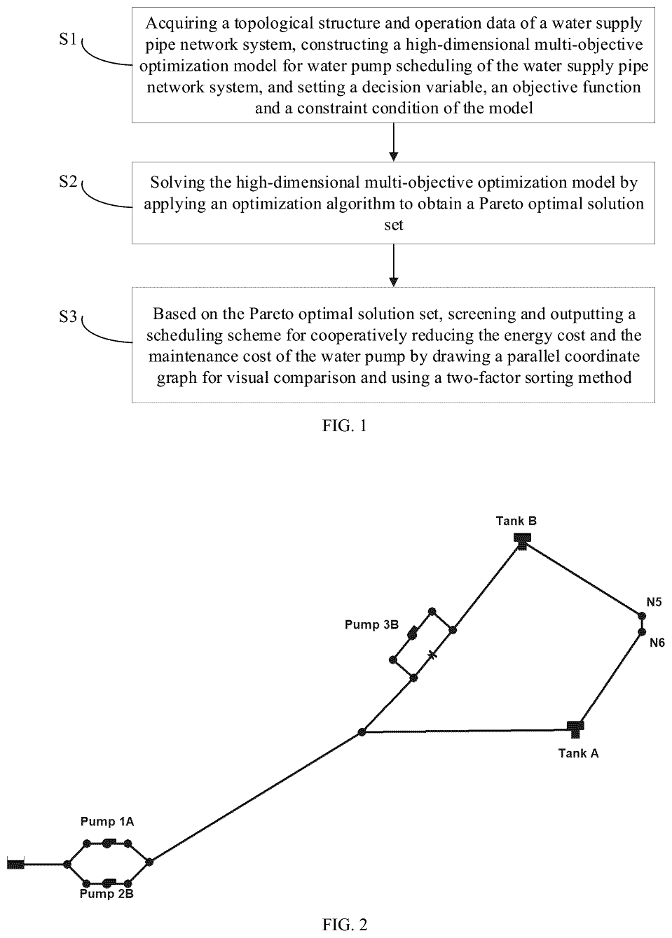

This embodiment provides a scheduling method for uniformly reducing energy and maintenance costs of a water supply pipe network system, and FIG. 1 is a flow chart of the scheduling method in this embodiment.

The scheduling method for uniformly reducing the energy and maintenance costs of the water supply pipe network system provided by this embodiment comprises the following steps.

In S1, a topological structure and operation data of a water supply pipe network system are acquired, a high-dimensional multi-objective optimization model for water pump scheduling of the water supply pipe network system is constructed, and a decision variable, an objective function and a constraint condition of the model are set.

The high-dimensional multi-objective optimization model takes an energy cost and a maintenance cost of each water pump in the water supply pipe network system as independent optimization objectives.

The operation data of the water supply pipe network system acquired in this step comprises, but is not limited to, operation conditions and actual peak-valley price periods of each water pump and each water tank, and an operation requirement of the water supply pipe network system.

In one optional embodiment, the step S1 specifically comprises the following steps.

In S11, the topological structure of the water supply pipe network system is acquired, a control correlation between each water pump and each water tank is determined, and the decision variable of the scheduling model is set according to a logical control rule of each water pump.

In S12, calculation methods of the energy cost and the maintenance cost of the water pump are determined according to the actual peak-valley price period for setting the objective function of the scheduling model.

In S13, the constraint condition of the scheduling model is set according to the operation requirement of the water supply pipe network system.

Further, in one optional embodiment, in the step S11, the control correlation between the water pump and the water tank is determined according to the topological structure and an operation mode of the water supply pipe network; and the decision variable comprises a switch control water level of each water pump associated with each water tank at a peak-valley price, and the control rule of each water pump is set by using rule-based control functions in EPANET 2.2.

Further, in one optional embodiment, in the step S12, the objective function of the high-dimensional multi-objective optimization model comprises minimizing the energy cost and the maintenance cost of each water pump; and an expression of the objective function is as follows:

$$\{ \begin{matrix}min {C}_{E}^{1} \\ min {C}_{E}^{2} \\ … \\ min {C}_{E}^{NP} \\ \\ min {C}_{M}^{1} \\ min {C}_{M}^{2} \\ … \\ min {C}_{M}^{NP}\end{matrix}$$

wherein, NP represents a number of pumps, C_{E}ⁱ represents an energy cost of a water pump i, and C_{M}ⁱ represents a maintenance cost of the water pump i; wherein, the energy cost of the water pump comprises an electricity charge of one simulation cycle, and the maintenance cost of the water pump comprises a total number of switches of one simulation cycle.

In the objective function, C_{E}ⁱ represents the energy cost of the water pump, and an expression of the energy cost is as follows:

$${C}_{E}^{i} = {\sum }_{t = 1}^{N T} {P}_{t} \times {E}_{t}^{i} \times {S}_{t}^{i}$$

wherein, NT represents that operation time of the water pump is divided into several time intervals (NT), Pₜ represents a unit energy consumption price at a time interval t, Eₜⁱ represents power (kw) of the water pump i at the time interval t, and Sₜⁱ represents working time (hr) of a pump n at the time interval t. A calculation formula of the power Eₜⁱ is as follows:

$${E}_{t}^{i} = \frac{{10}^{- 3} \times γ \times {Q}_{t}^{i} \times {H}_{t}^{i}}{{η}_{t}^{i}}$$

wherein, γ represents a specific gravity (N/m³) of water, Oₜⁱ and Hₜⁱ respectively represent a flow rate (m³/s) and a head (m) passing through the water pump i at the time interval t, and ηₜⁱ represents efficiency (%) of the water pump i at the time interval t.

In the objective function, C_{M}ⁱ represents the maintenance cost of the water pump i. Because it is difficult to quantify the maintenance cost of the water pump, a surrogate index is used for estimation in this embodiment. Specifically, a total number of switches of the water pump is used instead of the maintenance cost, and one switch action of the water pump refers to an action of switching on the water pump stopped operating at the last time interval. The maintenance cost of the water pump i is the total number of switches of the water pump in a simulation period, and an expression of the maintenance cost is as follows:

$${C}_{M}^{i} = {\sum }_{t = 1}^{NT} {r}_{t}^{i}$$

wherein, rₜⁱ represents one switch action of the water pump i.

Further, in one optional embodiment, the constraint condition in the step S13 comprises mass conservation of nodes and energy conservation of pipe sections in the water supply pipe network system, limited water levels in different time periods of each water tank, a switch time interval of the water pump, and a minimum service pressure constraint of a water demand node.

In S2, the high-dimensional multi-objective optimization model is solved by applying an optimization algorithm to obtain a Pareto optimal solution set.

The optimization algorithm used in this embodiment should have an execution strategy to effectively overcome “dominant resistance” of a high-dimensional multi-objective space, so as ensure that the algorithm does not easily fall into a local optimal solution.

In S3, based on the Pareto optimal solution set, a scheduling scheme for cooperatively reducing the energy cost and the maintenance cost of the water pump is screened and output by drawing a parallel coordinate graph for visual comparison and using a two-factor sorting method.

In one optional embodiment, the step S3 specifically comprises the following step of: drawing the Pareto optimal solution in the parallel coordinate graph, screening an energy-saving scheduling scheme with a comprehensive benefit advantage as the scheduling scheme for cooperatively reducing the energy cost and the maintenance cost of the water pump through the two-factor sorting method and the visual comparison analysis, and outputting the scheduling scheme.

In this embodiment, by constructing the high-dimensional multi-objective optimization model for water pump scheduling of the water supply pipe network system, and taking the energy cost and the maintenance cost of each water pump as the independent optimization objectives, a uniform scheduling strategy is sought from a microscopic perspective of a scheduling object, and an energy-saving scheduling scheme for a pumping station with a more comprehensive efficiency advantage can be found, so that the energy cost and the maintenance cost of the water supply pipe network system are significantly reduced, and a load imbalance problem existing in a traditional optimal scheduling model for the pumping station is effectively solved.

### Embodiment 2

The scheduling method provided in Embodiment 1 is applied to a vanZyl pipe network in this embodiment.

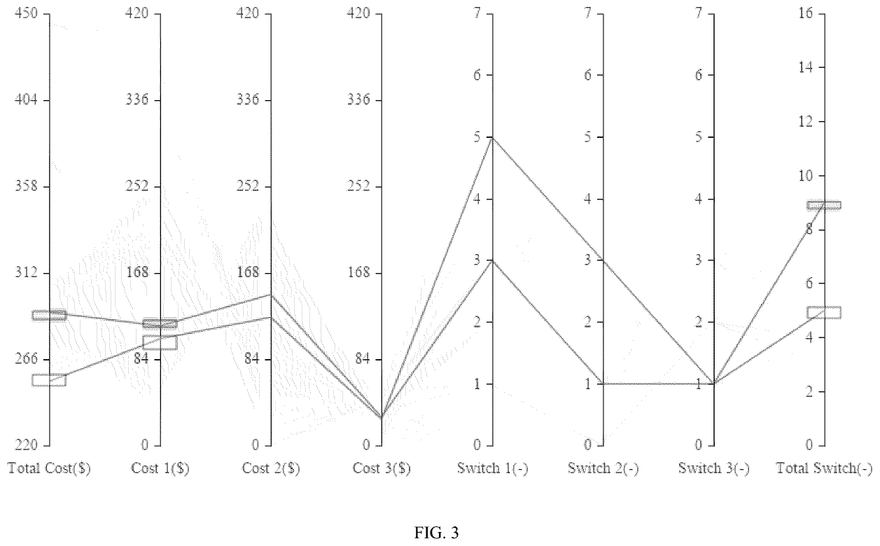

As shown in FIG. 2, a topological structure of the vanZyl pipe network in this embodiment comprises a water source, 15 pipelines and 13 nodes. Two water tanks (A and B) with different tank bottom elevations, a main pumping station (comprising water pumps 1A and 2B) and a pressurized pumping station (water pump 3B) are arranged in the pipe network system.

The main pumping station is provided with two identical pumps 1A and 2B connected in parallel, the pump 1A is controlled by a water level of the water tank A, the pump 2B is controlled by a water level of the water tank B, and the pressurized pump 3B is connected with the water tank B with a higher tank bottom elevation, with an operation rule controlled by the water level of the water tank B. When the main pumping station works, the pressurized pump 3B delivers water to the water tank B; when both the water pumps 1A and 2B do not operate, the pressurized pump 3B will deliver water from the water tank A to the water tank B.

Firstly, a high-dimensional multi-objective optimization model for water pump scheduling is constructed and parameters are set.

Operation control of the water pump in the water supply pipe network system is simulated by using EPANET 2.2 in this embodiment.

The EPANET 2.2 is a computer program capable of executing delay simulation of hydraulic power and water quality of a water supply pipe network, has a relatively perfect simulation function of the water supply pipe network, and can meet an analysis requirement of water pump scheduling.

Rule-based control functions in the EPANET 2.2 are used for the control of the water pump, so that the operation of the water pump can be controlled more flexibly. A writing method of the rule-based control functions mainly consists of three parts: a conditional premise, an action executed when conditions are met and an action executed when conditions are not met, such as:

$$\begin{matrix}IF SYSTEM CLOCKTIME > 0 : 00 : 00 AM \\ AND SYSTEM CLOCKTIME <= 7 : 00 : 00 AM \\ THEN PUMP 1 ASTATUS IS OPEN \\ ELSE PUMP 2 B SETTING IS OPEN\end{matrix}$$

According to requirements, a switch time interval t of the water pump is set, such as 1 hour.

The high-dimensional multi-objective optimization model for water pump scheduling in the vanZyl pipe network is constructed by the method provided in Embodiment 1, wherein, in power calculation of the water pump, a specific gravity γ of water is 9, 800 N/m³, a final water level of the water tank should be greater than or equal to an initial water level, a minimum service pressure of a water demand node is Pₘᵢₙ=28 m, and a simulation cycle is 24 hours.

Subsequently, the high-dimensional multi-objective optimization model for water pump scheduling is solved by using a Borg algorithm.

For the vanZyl pipe network, each solution comprises 12 decision variables (each water pump corresponds to 4 decision variables, which are switch control water levels in a peak-valley price period), and a value range of each decision variable depends on a water level range of an associated water tank. In the vanZyl pipe network, the water tank A has a highest water level of 5.00 m and a lowest water level of 0.00 m, and a minimum variable step size of the water level is 0.01 m, which means that there are 50 optional water level values of the decision variables controlled by the water tank A. The water tank B has a highest water level of 10.00 m and a lowest water level of 0.00 m, and a minimum variable step size of the water level is 0.01 m, which means that there are 100 optional water level values of the decision variables controlled by the water tank B. Therefore, for the water pump 1A, a solution space of the objective function is 50⁴, for the water pumps 2B and 3B, a solution space of the objective function is 100⁴, and a solution space of the whole model for water pump scheduling is 50⁴×100⁴.

In this embodiment, the high-dimensional multi-objective optimization model for water pump scheduling is solved by selecting a Borg optimization algorithm. The Borg is an advanced evolutionary algorithm developed to effectively solve a high-dimensional multi-objective optimization problem. According to a scale of the solution space of the water pump scheduling problem in the vanZyl pipe network, parameters of the Borg algorithm are set as follows: an initial population size is 100, and a total number of evaluations is 500,000.

Finally, an optimization solution is analyzed to obtain an optimization scheme.

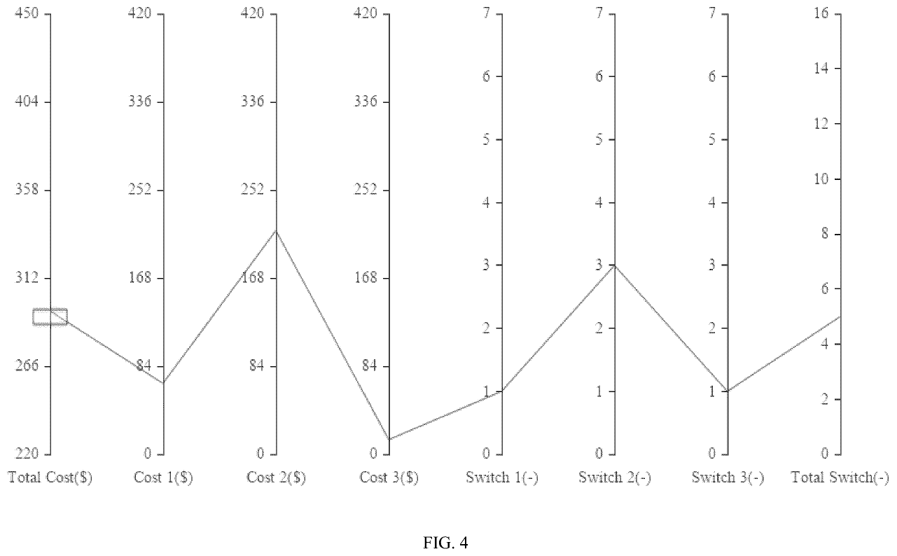

FIG. 3 shows a Pareto optimal solution set obtained through the high-dimensional multi-objective optimization model for water pump scheduling. Except for two representative schemes (dark gray multi-segment broken lines), other solutions are all presented by light gray multi-segment broken lines. FIG. 4 shows a Pareto optimal solution set obtained under identical parameters of the Borg by minimizing a total energy cost and a total maintenance cost of a vanZyl water supply pipe network system as an objective function. Except for one representative scheme (dark gray multi-segment broken line), other solutions are all presented by light gray multi-segment broken lines.

As shown in FIG. 3, there are a total of six objectives in this embodiment, an index corresponding to each solution is represented by numerical values on six parallel ordinate axes in the middle. In addition, two parallel ordinate axes are added in FIG. 3, which respectively represent a total energy cost (Total Cost) and a total number of switches (Total Switch) of the vanZyl pipe network.

By comparing FIG. 3 and FIG. 4, it can be seen that, with the reduction of the total energy cost, the total number of switches shows an upward trend, which means that the energy cost of the pumping station can be effectively reduced by flexibly adjusting the switch operation of the water pump. It can be seen from the total energy cost in FIG. 3 that, for the scheme obtained by using the high-dimensional multi-objective optimization model for water pump scheduling, a rationality of the scheme may be evaluated in multiple dimensions, so as to find a solution more suitable for the scheduling requirement. The solution marked in FIG. 4 is a representative solution with a lowest total energy cost in the case of double objectives, which has a total energy cost of 294.74 $/day and a total number of switches of 5. It can be seen from the coordinate axis of the total energy cost in FIG. 3 that a large number of schemes with a lower total energy cost can be found by the present invention, and one of the representative schemes has a total energy cost of 254.18 $/day and a total number of switches of 9. Even in the case of the same total number of switches (5), the schemes with the lower total energy cost can also be found by the present invention, such as another representative scheme in FIG. 3, which has a total energy cost of 290.95 $/day.

It can also be seen from the representative solutions in FIG. 3 and FIG. 4 that, in the case of the same total number of switches, an operation load of each water pump is more uniform in the scheduling scheme obtained by the present invention. In FIG. 4, an energy cost (Cost 1) of a water pump 1 is 67.54 $/day, an energy cost (Cost 2) of a water pump 2 is 213.24 $/day, and an energy cost (Cost 3) of a water pump 3 is 13.94 $/day. In FIG. 3, the energy cost of the water pump 1 is 116.33 $/day, the energy cost of the water pump 2 is 146.87 $/day, and the energy cost of the water pump 3 is 27.73 $/day. The representative scheme shown in FIG. 3 effectively avoids excessive use of the water pump 2 in FIG. 4, and a use intensity among the three water pumps in the water supply pipe network system is more uniform.

### Embodiment 3

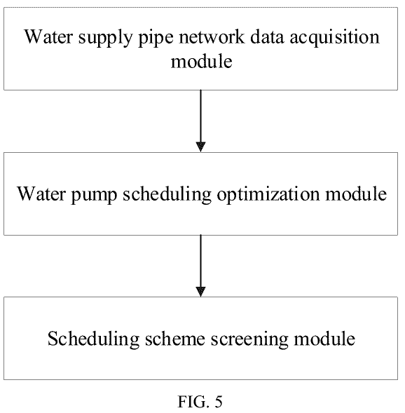

This embodiment provides a scheduling system for uniformly reducing energy and maintenance costs of a water supply pipe network system, which applies the scheduling method provided in Embodiment 1. FIG. 5 is an architecture diagram of the scheduling system in this embodiment.

The scheduling system for uniformly reducing the energy and maintenance costs of the water supply pipe network system provided in this embodiment comprises a water supply pipe network data acquisition module, a water pump scheduling optimization module and a scheduling scheme screening module.

In this embodiment, the water pump scheduling optimization module is configured with the high-dimensional multi-objective optimization model, the decision variable, the objective function and the constraint condition are preset for the high-dimensional multi-objective optimization model, and the high-dimensional multi-objective optimization model takes the energy cost and the maintenance cost of each water pump as the independent optimization objectives.

The water pump scheduling optimization module solves the high-dimensional multi-objective optimization model for water pump scheduling by applying the optimization algorithm to obtain the Pareto optimal solution set.

The optimization algorithm used in this embodiment should have an execution strategy to effectively overcome “dominant resistance” of a high-dimensional multi-objective space, so as ensure that the algorithm does not easily fall into a local optimal solution.

In this embodiment, the water supply pipe network data acquisition module is configured for acquiring a topological structure and operation data of a current water supply pipe network system, and updating parameters of the high-dimensional multi-objective optimization model in the water pump scheduling optimization module.

In this embodiment, the scheduling scheme screening module is configured for screening and outputting the scheduling scheme for cooperatively reducing the energy cost and the maintenance cost of the water pump by drawing the parallel coordinate graph for visual comparison and using the two-factor sorting method according to the Pareto optimal solution set generated by the water pump scheduling optimization module.

In one optional embodiment, the water supply pipe network data acquisition module acquires the topological structure and the operation data of the current water supply pipe network system, determines the control correlation between each water pump and each water tank, and obtains the logical control rule of each water pump for updating the decision variable of the high-dimensional multi-objective optimization model.

The water supply pipe network data acquisition module further determines the calculation methods of the energy cost and the maintenance cost of the water pump for updating the objective function of the high-dimensional multi-objective optimization model according to the acquired actual peak-valley price period.
the water supply pipe network data acquisition module further updates the constraint condition of the high-dimensional multi-objective optimization model according to the acquired operation requirement of the water supply pipe network system.

Further optionally, in the decision variable of the high-dimensional multi-objective optimization model, the control correlation between each water pump and each water tank is determined according to the topological structure and an operation mode of the water supply pipe network. The decision variable comprises a switch control water level of each water pump associated with each water tank at a peak-valley price, and the control rule of each water pump is set by using rule-based control functions in EPANET 2.2.

Further optionally, the objective function of the high-dimensional multi-objective optimization model comprises minimizing the energy cost and the maintenance cost of each water pump; and an expression of the objective function is as follows:

$$\{ \begin{matrix}min {C}_{E}^{1} \\ min {C}_{E}^{2} \\ … \\ min {C}_{E}^{NP} \\ \\ min {C}_{M}^{1} \\ min {C}_{M}^{2} \\ … \\ min {C}_{M}^{NP}\end{matrix}$$

wherein, NP represents a number of pumps, C_{E}ⁱ represents an energy cost of a water pump i, and C_{M}ⁱ represents a maintenance cost of the water pump i; wherein, the energy cost of the water pump comprises an electricity charge of one simulation cycle, and the maintenance cost of the water pump comprises a total number of switches of one simulation cycle.

Further optionally, the constraint condition in the comprises mass conservation of nodes and energy conservation of pipe sections in the water supply pipe network system, limited water levels in different time periods of each water tank, a switch time interval of the water pump, and a minimum service pressure constraint of a water demand node.

### Embodiment 4

This embodiment provides a scheduling device, which comprises a memory and a processor, wherein the memory stores a computer program, and when executing the computer program, the processor implements the steps in the scheduling method for uniformly reducing the energy and maintenance costs of the water supply pipe network system provided in Embodiment 1.

Obviously, the above-mentioned embodiments of the present invention are merely examples for clearly illustrating the present invention, but are not intended to limit the implementations of the present invention. For those of ordinary skills in the art, other different forms of changes or variations may be made on the basis of the above description. It is not necessary or possible to exhaust all the implementations herein. Any modifications, equivalent substitutions, and improvements made within the spirit and principle of the present invention shall all fall within the scope of protection claimed by the present invention.

We claim:

1. A scheduling method for uniformly reducing energy and maintenance costs of a water supply pipe network system, comprising the following steps of:
S1: acquiring a topological structure and operation data of the water supply pipe network system, constructing a high-dimensional multi-objective optimization model for water pump scheduling of the water supply pipe network system, and setting a decision variable, an objective function and a constraint condition of the model, wherein the high-dimensional multi-objective optimization model takes an energy cost and a maintenance cost of each water pump in the water supply pipe network system as independent optimization objectives;
S2: solving the high-dimensional multi-objective optimization model by applying an optimization algorithm to obtain a Pareto optimal solution set; and
S3: based on the Pareto optimal solution set, screening and outputting a scheduling scheme for cooperatively reducing the energy cost and the maintenance cost of the water pump by drawing a parallel coordinate graph for visual comparison and using a two-factor sorting method.

2. The scheduling method according to claim 1, wherein the operation data of the water supply pipe network system comprises operation conditions and actual peak-valley price periods of each water pump and each water tank, and an operation requirement of the water supply pipe network system.

3. The scheduling method according to claim 2, wherein the step S1 specifically comprises the following steps of:
S11: acquiring the topological structure of the water supply pipe network system, determining a control correlation between each water pump and each water tank, and setting the decision variable of the scheduling model according to a logical control rule of each water pump;
S12: determining calculation methods of the energy cost and the maintenance cost of the water pump according to the actual peak-valley price period for setting the objective function of the scheduling model; and
S13: setting the constraint condition of the scheduling model according to the operation requirement of the water supply pipe network system.

4. The scheduling method according to claim 3, wherein, in the step S11, the control correlation between each water pump and each water tank is determined according to the topological structure and an operation mode of the water supply pipe network; and the decision variable comprises a switch control water level of each water pump associated with each water tank at a peak-valley price, and the control rule of each water pump is set by using rule-based control functions in EPANET 2.2.

5. The scheduling method according to claim 3, wherein the objective function of the high-dimensional multi-objective optimization model comprises minimizing the energy cost and the maintenance cost of each water pump; and an expression of the objective function is as follows:
$$\{ \begin{matrix}min {C}_{E}^{1} \\ min {C}_{E}^{2} \\ … \\ min {C}_{E}^{NP} \\ \\ min {C}_{M}^{1} \\ min {C}_{M}^{2} \\ … \\ min {C}_{M}^{NP}\end{matrix}$$
wherein, NP represents a number of pumps, C_{E}ⁱ represents an energy cost of a water pump i, and C_{M}ⁱ represents a maintenance cost of the water pump i; wherein, the energy cost of the water pump comprises an electricity charge of one simulation cycle, and the maintenance cost of the water pump comprises a total number of switches of one simulation cycle.

6. The scheduling method according to claim 3, wherein the constraint condition comprises mass conservation of nodes and energy conservation of pipe sections in the water supply pipe network system, limited water levels in different time periods of each water tank, a switch time interval of the water pump, and a minimum service pressure constraint of a water demand node.

7. The scheduling method according to a claim 1, wherein the step S3 specifically comprises the following step of: drawing the Pareto optimal solution in the parallel coordinate graph, screening an energy-saving scheduling scheme with a comprehensive benefit advantage as the scheduling scheme for cooperatively reducing the energy cost and the maintenance cost of the water pump through the two-factor sorting method and the visual comparison analysis, and outputting the scheduling scheme.

8. A scheduling system for uniformly reducing energy and maintenance costs of a water supply pipe network system, applying the scheduling method according to claim 1, and comprising a water supply pipe network data acquisition module, a water pump scheduling optimization module and a scheduling scheme screening module, wherein:
the water pump scheduling optimization module is configured with the high-dimensional multi-objective optimization model, the decision variable, the objective function and the constraint condition are preset for the high-dimensional multi-objective optimization model, and the high-dimensional multi-objective optimization model takes the energy cost and the maintenance cost of each water pump as the independent optimization objectives;
the water pump scheduling optimization module solves the high-dimensional multi-objective optimization model for water pump scheduling by applying the optimization algorithm to obtain the Pareto optimal solution set;
the water supply pipe network data acquisition module is configured for acquiring a topological structure and operation data of a current water supply pipe network system, and updating parameters of the high-dimensional multi-objective optimization model in the water pump scheduling optimization module; and
the scheduling scheme screening module is configured for screening and outputting the scheduling scheme for cooperatively reducing the energy cost and the maintenance cost of the water pump by drawing the parallel coordinate graph for visual comparison and using the two-factor sorting method according to the Pareto optimal solution set generated by the water pump scheduling optimization module.

9. The scheduling system according to claim 8, wherein the water supply pipe network data acquisition module acquires the topological structure and the operation data of the current water supply pipe network system, determines the control correlation between each water pump and each water tank, and obtains the logical control rule of each water pump for updating the decision variable of the high-dimensional multi-objective optimization model;
the water supply pipe network data acquisition module further determines the calculation methods of the energy cost and the maintenance cost of the water pump for updating the objective function of the high-dimensional multi-objective optimization model according to the acquired actual peak-valley price period; and
the water supply pipe network data acquisition module further updates the constraint condition of the high-dimensional multi-objective optimization model according to the acquired operation requirement of the water supply pipe network system.

10. A scheduling device, comprising a memory and a processor, wherein the memory stores a computer program, and when executing the computer program, the processor implements the steps in the scheduling method for uniformly reducing the energy and maintenance costs of the water supply pipe network system according to claim 1.
